(19) United States
(12) Patent Application Publication
(10) Pub. No.: US 2025/0300622 A1
(43) Pub. Date: Sep. 25, 2025

(54) SURFACE ACOUSTIC WAVE DEVICE HAVING MULTILAYER PIEZOELECTRIC SUBSTRATE WITH HIGH DENSITY INTERDIGITAL TRANSDUCER ELECTRODES AND NEGATIVE TEMPERATURE COMPENSATION LAYER

(71) Applicant: SKYWORKS SOLUTIONS, INC., Irvine, CA (US)

(72) Inventors: Rei Goto, Osaka-Shi (JP); Michael David Hill, Emmitsburg, MD (US)

(21) Appl. No.: 19/077,715

(22) Filed: Mar. 12, 2025

Related U.S. Application Data
(60) Provisional application No. 63/567,178, filed on Mar. 19, 2024.

(51) Int. Cl. H03H 9/02; H03H 9/25; H03H 9/64

(52) U.S. Cl. CPC H03H 9/02834; H03H 9/02574; H03H 9/25; H03H 9/6483

(57) ABSTRACT

Aspects and embodiments disclosed herein include a surface acoustic wave device comprising a support substrate, a first functional layer having a positive temperature coefficient of frequency disposed above an upper surface of the support substrate, a second functional layer having a negative temperature coefficient of frequency disposed on an upper surface of the first functional layer, a layer of piezoelectric material disposed on an upper surface of the second functional layer, and interdigital transducer (IDT) electrodes including interdigitated electrode fingers disposed on a surface of the piezoelectric material layer, the IDT electrodes including a metal with a density greater than aluminum.

### CROSS-REFERENCE TO RELATED APPLICATIONS

This application claims priority under 35 U.S.C. § 119(e) to U.S. Provisional Patent Application Ser. No. 63/567,178, titled “SURFACE ACOUSTIC WAVE DEVICE HAVING MULTILAYER PIEZOELECTRIC SUBSTRATE WITH HIGH DENSITY INTERDIGITAL TRANSDUCER ELECTRODES AND NEGATIVE TEMPERATURE COMPENSATION LAYER,” filed Mar. 19, 2024, the entire content of which is incorporated herein by reference for all purposes.

### BACKGROUND

### Technical Field

Embodiments of this disclosure relate to acoustic wave devices with improved electromechanical coupling coefficients to facilitate high bandwidth operations as well as low temperature coefficients of frequency.

### Description of Related Technology

Acoustic wave devices, for example, surface acoustic wave (SAW) and bulk acoustic wave (BAW) devices may be utilized as components of filters in radio frequency electronic systems. For instance, filters in a radio frequency front-end of a mobile phone can include acoustic wave filters. Two acoustic wave filters can be arranged as a duplexer.

### SUMMARY

In accordance with one aspect, there is provided a surface acoustic wave device. The surface acoustic wave device comprises a support substrate, a first functional layer having a positive temperature coefficient of frequency disposed above an upper surface of the support substrate, a second functional layer having a negative temperature coefficient of frequency disposed on an upper surface of the first functional layer, a layer of piezoelectric material disposed on an upper surface of the second functional layer, and interdigital transducer (IDT) electrodes including interdigitated electrode fingers disposed on a surface of the piezoelectric material layer, the IDT electrodes including a metal with a density greater than aluminum.

In some embodiments, the surface acoustic wave device further comprises a trap-rich layer disposed between the support substrate and the first functional layer.

In some embodiments, the trap-rich layer is formed of polysilicon.

In some embodiments, the support substrate is formed of silicon.

In some embodiments, the first functional layer is formed of silicon dioxide.

In some embodiments, the second functional layer is formed of a material exhibiting a greater acoustic velocity than the acoustic velocity of the material of the first functional layer.

In some embodiments, the second functional layer is formed of one of silicon nitride, silicon oxynitride, diamond, aluminum nitride, aluminum oxide, boron nitride, silicon carbide, cordierite, silicon oxycarbide, forsterite, magnesium aluminate spinel, magnesium titanate, yttrium oxide, samarium oxide, cerium oxide, hafnium oxide, tantalum oxide, zirconium titanate, barium nonatitante, niobium oxide, zirconium oxide, barium samarium titanate, titanium dioxide, or calcium titanate.

In some embodiments, the second functional layer is thinner than the first functional layer.

In some embodiments, the second functional layer is thinner than the layer of piezoelectric material.

In some embodiments, the first functional layer is thinner than the layer of piezoelectric material.

In some embodiments, the IDT electrodes include a first metal layer disposed on a second metal layer, the first metal layer being less dense and more conductive than the second metal layer.

In some embodiments, the first metal layer includes aluminum and the second metal layer includes one of molybdenum, tungsten, or platinum.

In some embodiments, the first metal layer has a thickness of between 0.025λ and 0.075λ, λ being a wavelength of a main acoustic wave generated by the surface acoustic wave device.

In some embodiments, the second metal layer has a thickness of between 0.0065λ and 0.08λ, λ being a wavelength of a main acoustic wave generated by the surface acoustic wave device.

In some embodiments, the surface acoustic wave device exhibits a temperature coefficient of frequency at its resonant frequency that has an absolute value of 10 ppm/° C. or less.

In some embodiments, the surface acoustic wave device exhibits a temperature coefficient of frequency at its anti-resonant frequency of less than −10 ppm/° C.

In some embodiments, the surface acoustic wave device exhibits an electromechanical coupling coefficient at its resonant frequency of at least 10%. In some embodiments, the layer of piezoelectric material is formed of lithium tantalate.

In some embodiments, the surface acoustic wave device is included in a radio frequency filter.

In some embodiments, the radio frequency filter is included in an electronics module. In some embodiments, the electronics module is included in an electronic device.

### BRIEF DESCRIPTION OF THE DRAWINGS

Embodiments of this disclosure will now be described, by way of non-limiting example, with reference to the accompanying drawings.

FIG. 1A is a simplified plan view of an example of a surface acoustic wave resonator;

FIG. 1B is a simplified plan view of another example of a surface acoustic wave resonator;

FIG. 1C is a simplified plan view of another example of a surface acoustic wave resonator;

FIG. 2 is a cross-sectional view of a portion of an example of a surface acoustic wave resonator;

FIG. 3A is a chart of temperature coefficient of frequency and electromechanical coupling coefficient of the resonator of FIG. 2 at its resonant frequency as a function of piezoelectric material (lithium tantalate) thickness and cut angle;

FIG. 3B is a chart of temperature coefficient of frequency and electromechanical coupling coefficient of the resonator of FIG. 2 at its anti-resonant frequency as a function of piezoelectric material (lithium tantalate) thickness and cut angle;

FIG. 4 is a cross-sectional view of a portion of an example of a surface acoustic wave resonator in accordance with aspects and embodiments disclosed herein;

FIG. 5A is a chart of temperature coefficient of frequency and electromechanical coupling coefficient of the resonator of FIG. 4 at its resonant frequency as a function of piezoelectric material (lithium tantalate) thickness and cut angle;

FIG. 5B is a chart of temperature coefficient of frequency and electromechanical coupling coefficient of the resonator of FIG. 4 at its anti-resonant frequency as a function of piezoelectric material (lithium tantalate) thickness and cut angle;

FIG. 6 is a comparison between acoustic velocities of the resonator structure of FIG. 2 and of FIG. 4 as a function of piezoelectric material (lithium tantalate) thickness and cut angle;

FIG. 7A illustrates acoustic velocity of a resonator structure as illustrated in FIG. 4 as a function of thickness of a lower Mo IDT electrode layer and thickness of a SiN layer disposed in the substrate;

FIG. 7B is another chart illustrating acoustic velocity of a resonator structure as illustrated in FIG. 4 as a function of thickness of a lower Mo IDT electrode layer and thickness of a SiN layer disposed in the substrate;

FIG. 8 is a schematic diagram of a radio frequency ladder filter;

FIG. 9 is a block diagram of one example of a filter module that can include one or more surface acoustic wave resonators according to aspects of the present disclosure;

FIG. 10 is a block diagram of one example of a front-end module that can include one or more filter modules according to aspects of the present disclosure;

FIG. 11 is a block diagram of one example of a wireless device including the front-end module of FIG. 10; and

FIG. 12 is a table of materials that may be utilized as a functional layer within the substrate of the acoustic wave resonator of FIG. 4.

### DETAILED DESCRIPTION OF CERTAIN EMBODIMENTS

The following description of certain embodiments presents various descriptions of specific embodiments. However, the innovations described herein can be embodied in a multitude of different ways, for example, as defined and covered by the claims. In this description, reference is made to the drawings where like reference numerals can indicate identical or functionally similar elements. It will be understood that elements illustrated in the figures are not necessarily drawn to scale. Moreover, it will be understood that certain embodiments can include more elements than illustrated in a drawing and/or a subset of the elements illustrated in a drawing. Further, some embodiments can incorporate any suitable combination of features from two or more drawings.

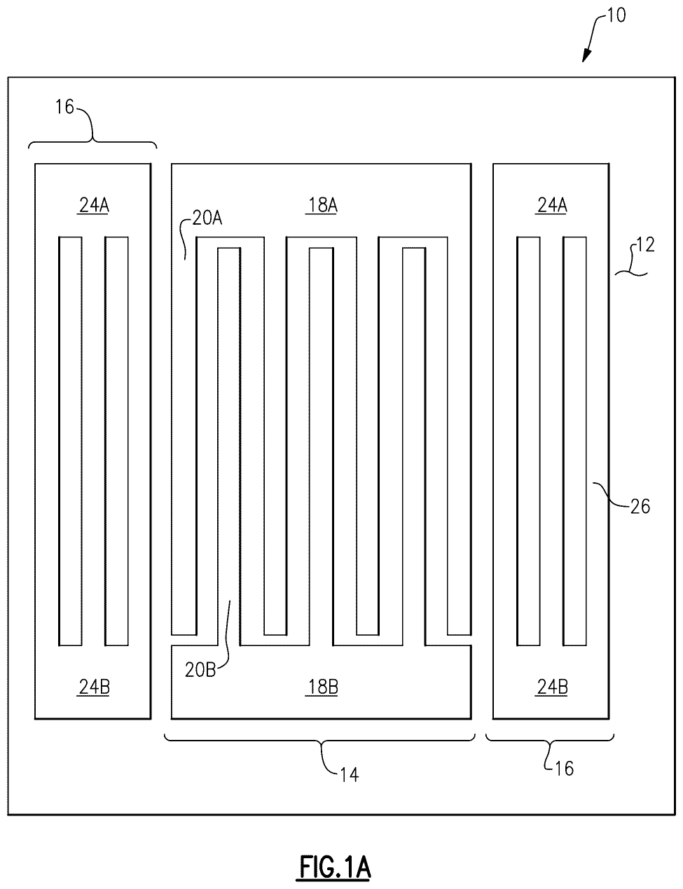

FIG. 1A is a plan view of a surface acoustic wave (SAW) resonator 10 such as might be used in a SAW filter, duplexer, balun, etc.

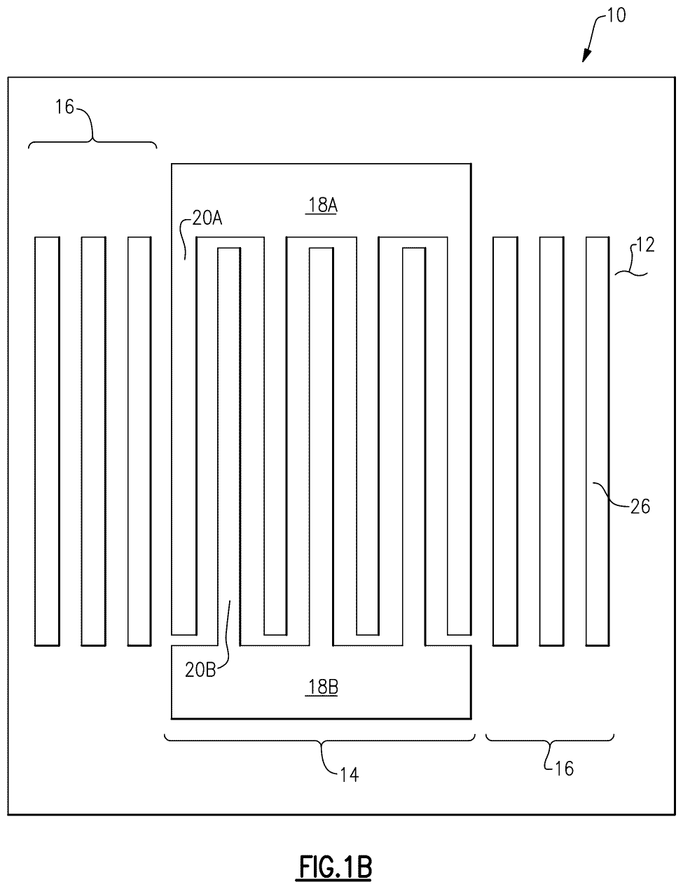

Acoustic wave resonator 10 is formed on a substrate 12 including a piezoelectric material layer, for example, a lithium tantalate (LiTaO₃) or lithium niobate (LiNbO₃) material layer. In some embodiment, as described with reference to FIG. 2 below, the substrate 12 may be a multilayer piezoelectric substrate (MPS). The acoustic wave resonator 10 includes Interdigital Transducer (IDT) electrodes 14 and reflector electrodes 16. In use, the IDT electrodes 14 excite a main acoustic wave having a wavelength λ along a surface of the substrate 12. The reflector electrodes 16 sandwich the IDT electrodes 14 and reflect the main acoustic wave back and forth through the IDT electrodes 14. The main acoustic wave of the device travels perpendicular to the lengthwise direction of the IDT electrodes.

The IDT electrodes 14 include a first bus bar electrode 18A and a second bus bar electrode 18B facing the first bus bar electrode 18A. The IDT electrodes 14 further include first electrode fingers 20A extending from the first bus bar electrode 18A toward the second bus bar electrode 18B, and second electrode fingers 20B extending from the second bus bar electrode 18B toward the first bus bar electrode 18A.

The reflector electrodes 16 (also referred to as reflector gratings) each include a first reflector bus bar electrode 24A and a second reflector bus bar electrode 24B and reflector fingers 26 extending between and electrically coupling the first bus bar electrode 24A and the second bus bar electrode 24B.

In other embodiments disclosed herein, as illustrated in FIG. 1B, the reflector bus bar electrodes 24A, 24B may be omitted and the reflector fingers 26 may be electrically unconnected. Further, as illustrated in FIG. 1C, acoustic wave resonators as disclosed herein may include dummy electrode fingers 20C that are aligned with respective electrode fingers 20A, 20B. Each dummy electrode finger 20C extends from the opposite bus bar electrode 18A, 18B than the respective electrode finger 20A, 20B with which it is aligned. It should be appreciated that the acoustic wave resonators 10 illustrated in FIGS. 1A-1C, as well as the other circuit elements illustrated in other figures presented herein, are illustrated in a highly simplified form. The relative dimensions of the different features are not shown to scale. Further, typical acoustic wave resonators would commonly include a far greater number of electrode fingers and reflector fingers than illustrated. Typical acoustic wave resonators or filter elements may also include multiple IDT electrodes sandwiched between the reflector electrodes.

FIG. 2 illustrates a cross-section of the substrate 12 and electrodes 20 that may be utilized in surface acoustic wave devices, for example, as illustrated in any of FIGS. 1A-1C above. The electrodes 20 of FIG. 2 may be any of the IDT electrodes 20A, 20B, the dummy electrodes 20C, or the reflector electrodes 26 of a surface acoustic wave device, for example, as illustrated in any of FIGS. 1A-1C above. The electrodes 20 will, however, be referred to herein as IDT electrodes 20. The IDT electrodes 20 may be multi-layer electrodes including a lower layer 20′ of a first metal and an upper layer 20″ of a second metal that is different from the first metal.

The substrate 12 is a MPS substrate including a support substrate 12A that may be formed of any of Si, quartz, sapphire, or any other suitable material to provide the substrate 12 with a desired amount of mechanical stability. A trap-rich layer 12B formed of, for example, polysilicon is disposed on top of the support substrate 12A and helps to reduce generation of parasitic currents at the upper surface of the support substrate 12A. A layer 12C of a dielectric material, for example, a 600 nm thick layer of SiO₂ is disposed on the upper surface of the trap-rich layer 12B. Layer 12C may be referred to herein as a first functional layer. A layer 12D of a piezoelectric material, for example, a 1,000 nm thick layer of lithium tantalate (LiTaO₃) or lithium niobate (LiNbO₃) is disposed on the upper surface of the layer 12C of dielectric material. The IDT electrodes 20 are disposed on the upper surface of the layer 12D of piezoelectric material. The piezoelectric material of layer 12D may exhibit a negative temperature coefficient of frequency. This may be compensated for by the positive temperature coefficient of frequency exhibited by the SiO₂ in the first functional layer 12C.

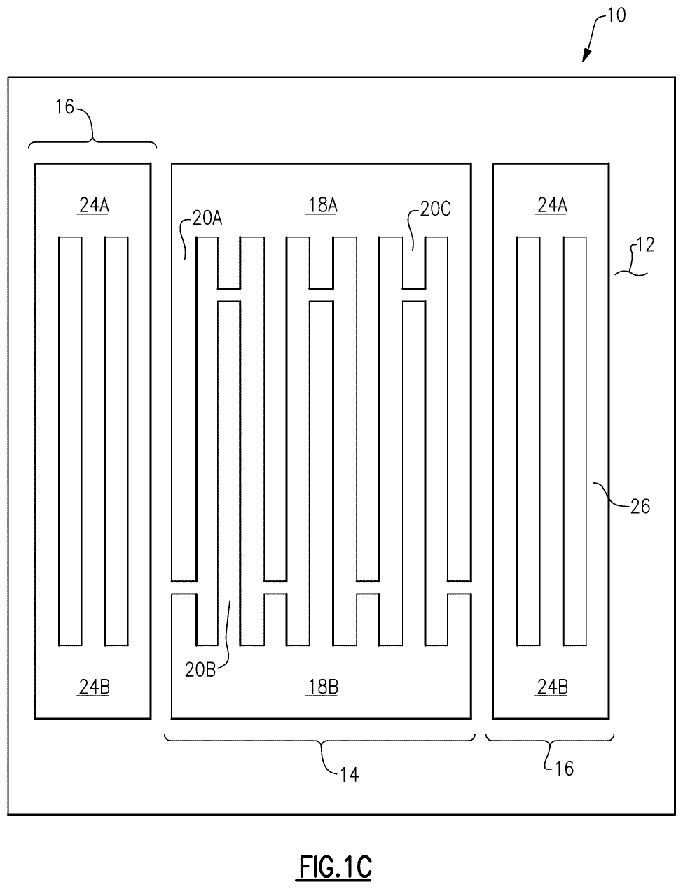

One undesirable effect of the use of the first functional layer 12C in the MPS substrate 12 is that it may be too effective in increasing the temperature coefficient of frequency of the SAW resonator. FIG. 3A is a chart of simulated results of the temperature coefficient of the resonant frequency (TCFs) of a SAW resonator having a MPS substrate 12 as illustrated in FIG. 2 for different thicknesses and cut angles of the piezoelectric material layer 12D when lithium tantalate (LT) is used as the piezoelectric material. Simulated results of the electromechanical coupling coefficient (K2) associated with the different LT thicknesses and cut angles is also illustrated in the chart of FIG. 3A. As illustrated, for each of the LT thicknesses investigated, as the cut angle of the LT is changed to increase the K2, the TCFs also increases. The TCFs levels exhibited when selecting the LT cut angle to achieve a desirable K2 value for the resonator may be higher than desired. Although this effect of increasing the TCF by more than desired might be avoided by using a thinner SiO₂ functional layer 12C, in some embodiments, reducing the thickness of the SiO₂ functional layer 12C below about 0.152 may adversely affect the K2 of the resonator.

FIG. 3B illustrates simulated results of the change in TCF at the anti-resonant frequency of the resonator (TCFₚ) as a function of K2 and LT thickness and cut angle.

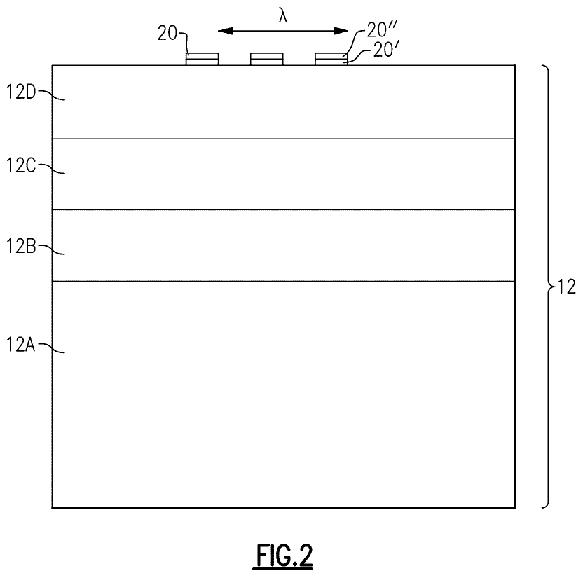

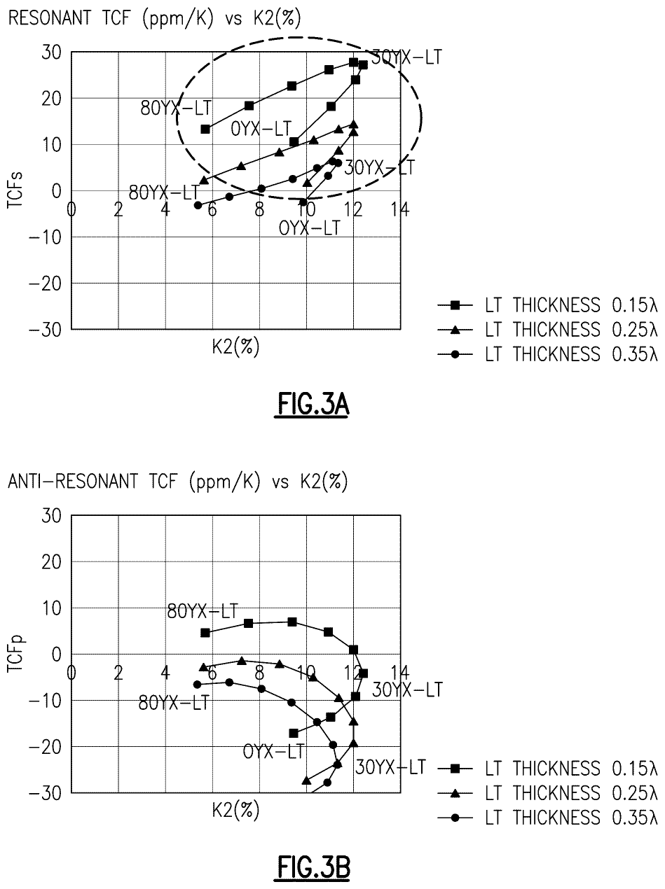

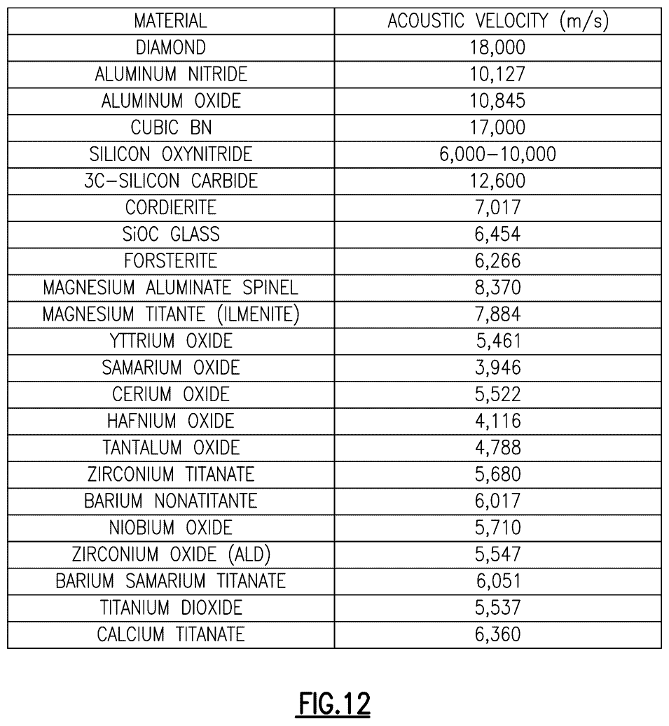

The inventors have discovered that one method by which the undesirably high TCFs of a SAW resonator having an MPS 12 as illustrated in FIG. 2 may be reduced to more desirable levels is to add a second functional layer that has a positive temperature coefficient of frequency into the MPS 12. As illustrated in FIG. 4, the second functional layer 12E may be added between the SiO₂ functional layer 12C and the piezoelectric material layer 12D. The second functional layer 12E may be, for example, a 200 nm thick layer of silicon nitride (SiN), although other materials may be utilized in different embodiments for the second functional layer 12E. FIG. 12 is a table of other possible materials that may be used for the second functional layer 12E and their acoustic velocities. The second functional layer may bring the TCFs of the resonator down to close to zero when selecting a LT thickness and cut angle that gives a desirable K2 as shown in FIG. 5A although the TCFₚ values are pushed to further negative levels as shown in FIG. 5B.

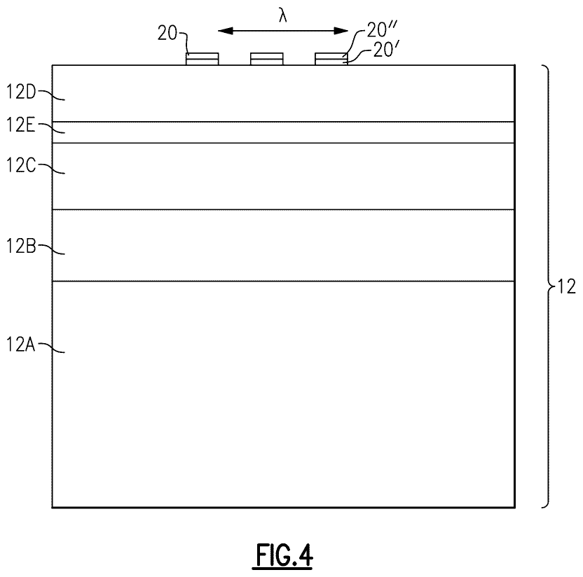

Materials such as SiN tend to exhibit an acoustic velocity V (about 10,200 m/s for Si₃N₄) that is higher than the acoustic velocity exhibited by SiO₂ (about 6,000 m/s) so inclusion of a second functional layer 12E formed of silicon nitride in the MPS 12 may increase the acoustic velocity (in m/s) of the resonator structure as a whole as illustrated in FIG. 6 for one example MPS SAW resonator. A SAW resonator structure exhibiting a higher acoustic velocity would have a greater λ and thus a greater size to achieve a desired operating frequency (resonant frequency or anti-resonant frequency) than a SAW resonator exhibiting a lower acoustic velocity. The inclusion of the second functional layer 12E formed of silicon nitride in the MPS 12 may thus result in undesirable increase in size of the resonator to achieve a desired operating frequency.

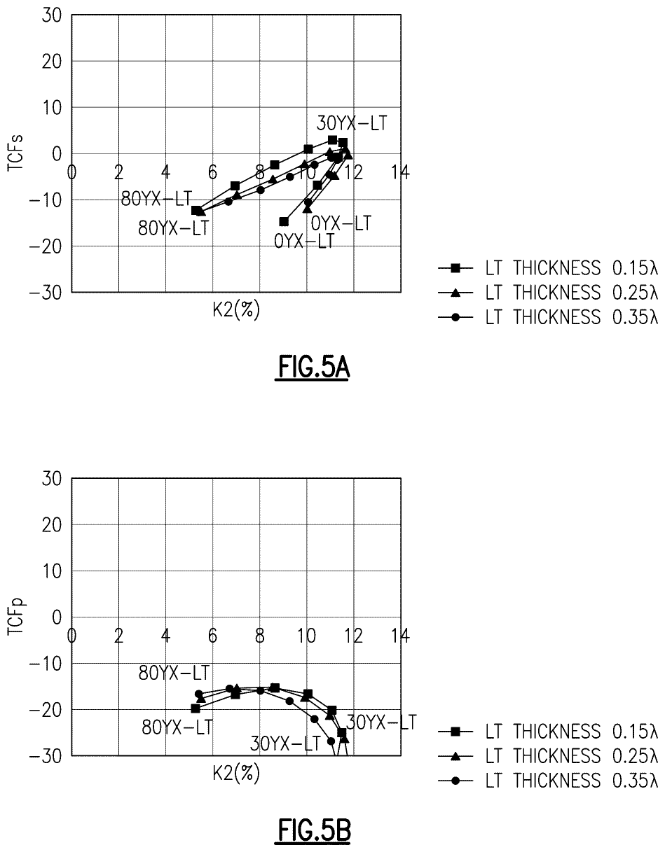

To compensate for the increase in acoustic velocity of an MPS SAW resonator structure due to the addition of a second functional layer 12E as described above, one may form the IDT electrodes 20, or at least one layer 20′ or 20″ of the IDT electrodes 20, of a high density metal such as Mo, W, Pt, or another metal having a density higher than Al. In some embodiments, the lower IDT electrode layer 20′ may be formed of the high density metal and the upper layer 20″ may be formed of Al or another metal with a higher conductivity than the lower layer 20′. FIGS. 7A and 7B illustrate results of a simulation of how the acoustic velocity of a resonator structure as illustrated in FIG. 4 changes with change in thickness of a lower IDT electrode layer 20′ formed of Mo and with changes in thickness of a second functional layer 12E formed of SiN, assuming an upper electrode layer 20″ formed of a 200 nm thick layer of Al and a λ value of 4 μm. From FIGS. 7A and 7B it can be observed that increasing the thickness of the Mo layer 20′ decreases the acoustic velocity for all thicknesses of the SiN second functional layer 12E. As can be seen most clearly in FIG. 7B a Mo layer thickness of 25 nm (0.0065λ) reduces the acoustic velocity of a resonator structure with a 200 nm thick SiN second functional layer 12E to the same acoustic velocity as the resonator structure formed without the Mo layer or SiN second functional layer 12E. It has been found that if the lower electrode layer 20′ thickness becomes too great the electromechanical coupling coefficient of the resonator may suffer, so in some embodiments, the thickness of the lower electrode layer 20′ may range between 25 nm (0.0065λ) and 320 nm (0.08λ) while the thickness of the upper electrode layer 20 may vary between 100 nm (0.025λ) and 300 nm (0.075λ).

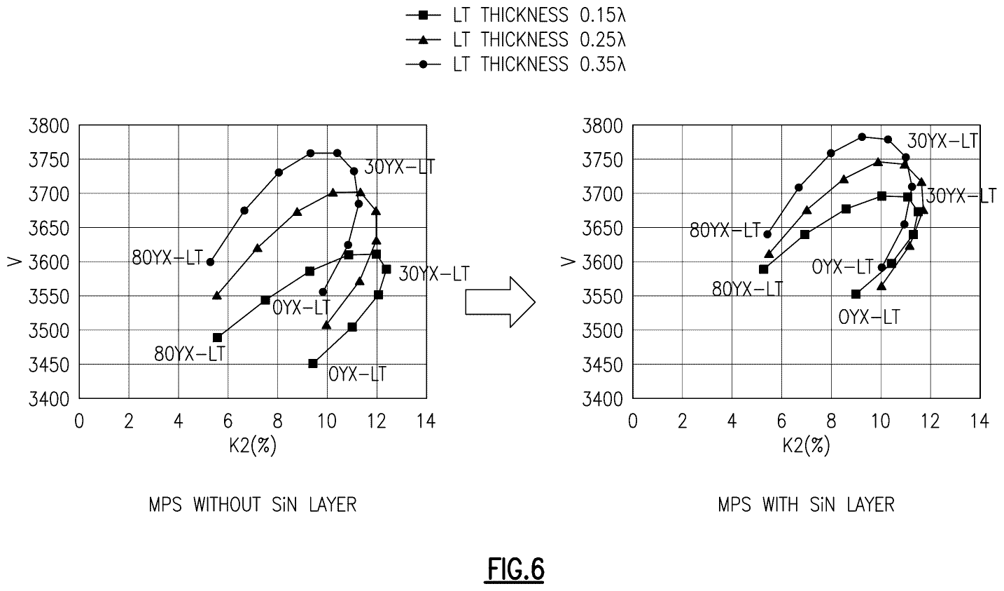

In some embodiments, multiple SAW resonators as disclosed herein may be combined into a filter, for example, an RF ladder filter schematically illustrated in FIG. 8 and including a plurality of series resonators R1, R3, R5, R7, and R9, and a plurality of parallel resonators R2, R4, R6, and R8. As shown, the plurality of series resonators R1, R3, R5, R7, and R9 are connected in series between the input and the output of the RF ladder filter, and the plurality of parallel resonators R2, R4, R6, and R8 are respectively connected between series resonators and ground in a shunt configuration. Other filter structures and other circuit structures known in the art that may include SAW devices or resonators, for example, duplexers, baluns, etc., may also be formed including examples of SAW resonators as disclosed herein.

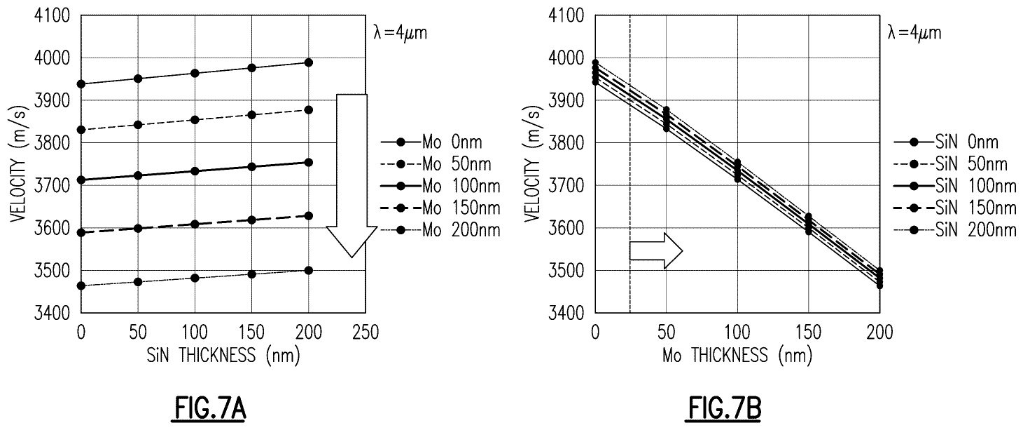

The acoustic wave resonators discussed herein can be implemented in a variety of packaged modules. Some example packaged modules will now be discussed in which any suitable principles and advantages of the packaged acoustic wave resonators discussed herein can be implemented. FIGS. 9, 10, and 11 are schematic block diagrams of illustrative packaged modules and devices according to certain embodiments.

As discussed above, embodiments of the surface acoustic wave elements can be configured as or used in filters, for example. In turn, a surface acoustic wave (SAW) filter using one or more surface acoustic wave elements may be incorporated into and packaged as a module that may ultimately be used in an electronic device, such as a wireless communications device, for example. FIG. 9 is a block diagram illustrating one example of a module 300 including a SAW filter 310. The SAW filter 310 may be implemented on one or more die(s) 320 including one or more connection pads 322. For example, the SAW filter 310 may include a connection pad 322 that corresponds to an input contact for the SAW filter and another connection pad 322 that corresponds to an output contact for the SAW filter. The packaged module 300 includes a packaging substrate 330 that is configured to receive a plurality of components, including the die 320. A plurality of connection pads 332 can be disposed on the packaging substrate 330, and the various connection pads 322 of the SAW filter die 320 can be connected to the connection pads 332 on the packaging substrate 330 via electrical connectors 334, which can be solder bumps or wirebonds, for example, to allow for passing of various signals to and from the SAW filter 310. The module 300 may optionally further include other circuitry die 340, for example, one or more additional filter(s), amplifiers, pre-filters, modulators, demodulators, down converters, and the like, as would be known to one of skill in the art of semiconductor fabrication in view of the disclosure herein. In some embodiments, the module 300 can also include one or more packaging structures to, for example, provide protection and facilitate easier handling of the module 300. Such a packaging structure can include an overmold formed over the packaging substrate 330 and dimensioned to substantially encapsulate the various circuits and components thereon.

Various examples and embodiments of the SAW filter 310 can be used in a wide variety of electronic devices. For example, the SAW filter 310 can be used in an antenna duplexer, which itself can be incorporated into a variety of electronic devices, such as RF front-end modules and communication devices.

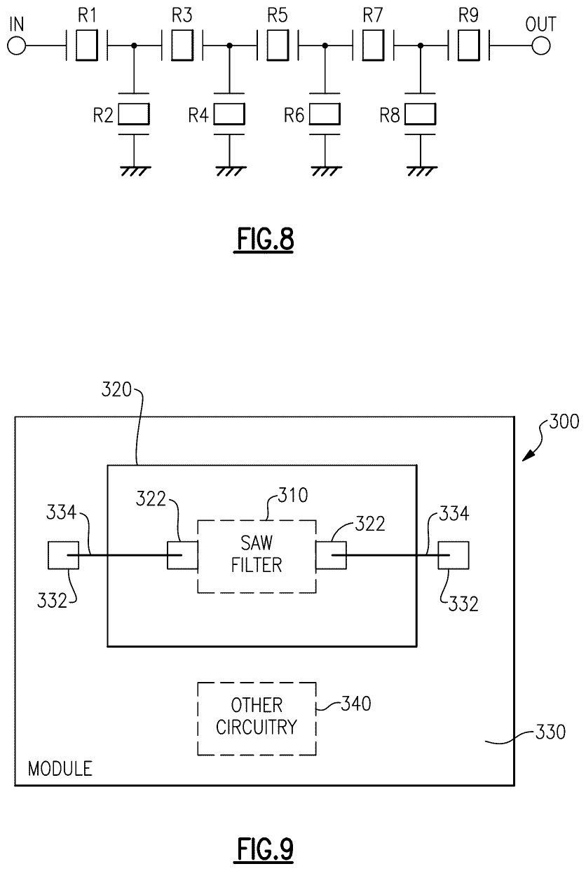

Referring to FIG. 10, there is illustrated a block diagram of one example of a front-end module 400, which may be used in an electronic device such as a wireless communications device (e.g., a mobile phone) for example. The front-end module 400 includes an antenna duplexer 410 having a common node 402, an input node 404, and an output node 406. An antenna 510 is connected to the common node 402.

The antenna duplexer 410 may include one or more transmission filters 412 connected between the input node 404 and the common node 402, and one or more reception filters 414 connected between the common node 402 and the output node 406. The passband(s) of the transmission filter(s) are different from the passband(s) of the reception filters. Examples of the SAW filter 310 can be used to form the transmission filter(s) 412 and/or the reception filter(s) 414. An inductor or other matching component 420 may be connected at the common node 402.

The front-end module 400 further includes a transmitter circuit 432 connected to the input node 404 of the duplexer 410 and a receiver circuit 434 connected to the output node 406 of the duplexer 410. The transmitter circuit 432 can generate signals for transmission via the antenna 510, and the receiver circuit 434 can receive and process signals received via the antenna 510. In some embodiments, the receiver and transmitter circuits are implemented as separate components, as shown in FIG. 10, however in other embodiments these components may be integrated into a common transceiver circuit or module. As will be appreciated by those skilled in the art, the front-end module 400 may include other components that are not illustrated in FIG. 10 including, but not limited to, switches, electromagnetic couplers, amplifiers, processors, and the like.

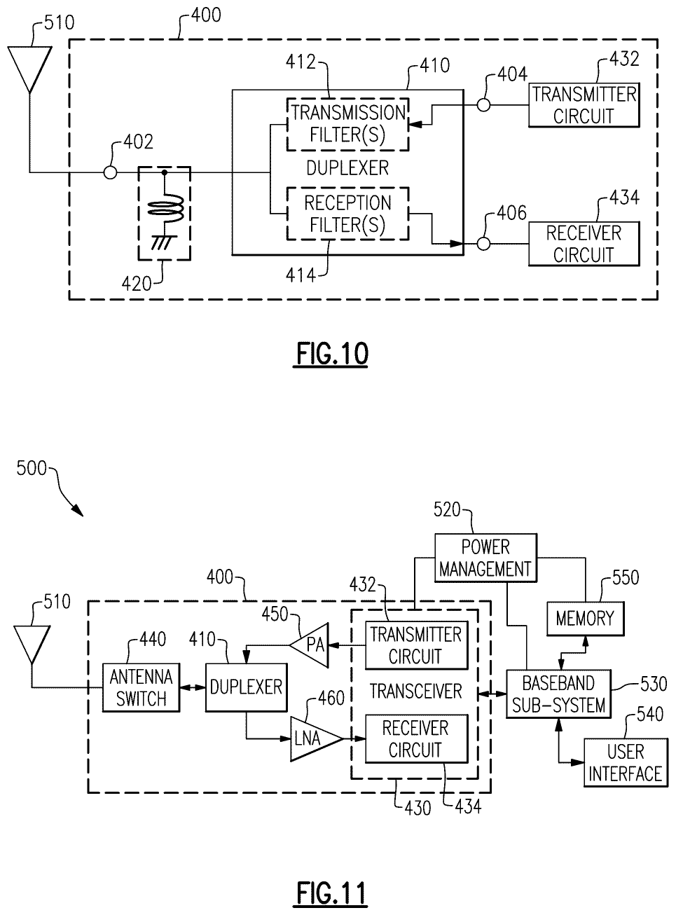

FIG. 11 is a block diagram of one example of a wireless device 500 including the antenna duplexer 410 shown in FIG. 10. The wireless device 500 can be a cellular phone, smart phone, tablet, modem, communication network or any other portable or non-portable device configured for voice or data communication. The wireless device 500 can receive and transmit signals from the antenna 510. The wireless device includes an embodiment of a front-end module 400 similar to that discussed above with reference to FIG. 10. The front-end module 400 includes the duplexer 410, as discussed above. In the example shown in FIG. 11 the front-end module 400 further includes an antenna switch 440, which can be configured to switch between different frequency bands or modes, such as transmit and receive modes, for example. In the example illustrated in FIG. 11, the antenna switch 440 is positioned between the duplexer 410 and the antenna 510; however, in other examples the duplexer 410 can be positioned between the antenna switch 440 and the antenna 510. In other examples the antenna switch 440 and the duplexer 410 can be integrated into a single component.

The front-end module 400 includes a transceiver 430 that is configured to generate signals for transmission or to process received signals. The transceiver 430 can include the transmitter circuit 432, which can be connected to the input node 404 of the duplexer 410, and the receiver circuit 434, which can be connected to the output node 406 of the duplexer 410, as shown in the example of FIG. 10.

Signals generated for transmission by the transmitter circuit 432 are received by a power amplifier (PA) module 450, which amplifies the generated signals from the transceiver 430. The power amplifier module 450 can include one or more power amplifiers. The power amplifier module 450 can be used to amplify a wide variety of RF or other frequency-band transmission signals. For example, the power amplifier module 450 can receive an enable signal that can be used to pulse the output of the power amplifier to aid in transmitting a wireless local area network (WLAN) signal or any other suitable pulsed signal. The power amplifier module 450 can be configured to amplify any of a variety of types of signal, including, for example, a Global System for Mobile (GSM) signal, a code division multiple access (CDMA) signal, a W-CDMA signal, a Long-Term Evolution (LTE) signal, or an EDGE signal. In certain embodiments, the power amplifier module 450 and associated components including switches and the like can be fabricated on gallium arsenide (GaAs) substrates using, for example, high-electron mobility transistors (pHEMT) or insulated-gate bipolar transistors (BiFET), or on a Silicon substrate using complementary metal-oxide semiconductor (CMOS) field effect transistors.

Still referring to FIG. 11, the front-end module 400 may further include a low noise amplifier module 460, which amplifies received signals from the antenna 510 and provides the amplified signals to the receiver circuit 434 of the transceiver 430.

The wireless device 500 of FIG. 11 further includes a power management sub-system 520 that is connected to the transceiver 430 and manages the power for the operation of the wireless device 500. The power management system 520 can also control the operation of a baseband sub-system 530 and various other components of the wireless device 500. The power management system 520 can include, or can be connected to, a battery (not shown) that supplies power for the various components of the wireless device 500. The power management system 520 can further include one or more processors or controllers that can control the transmission of signals, for example. In one embodiment, the baseband sub-system 530 is connected to a user interface 540 to facilitate various input and output of voice and/or data provided to and received from the user. The baseband sub-system 530 can also be connected to memory 550 that is configured to store data and/or instructions to facilitate the operation of the wireless device, and/or to provide storage of information for the user. Any of the embodiments described above can be implemented in association with mobile devices such as cellular handsets. The principles and advantages of the embodiments can be used for any systems or apparatus, such as any uplink wireless communication device, that could benefit from any of the embodiments described herein. The teachings herein are applicable to a variety of systems. Although this disclosure includes some example embodiments, the teachings described herein can be applied to a variety of structures. Any of the principles and advantages discussed herein can be implemented in association with RF circuits configured to process signals in a range from about 30 kHz to 5 GHz, such as in a range from about 600 MHz to 2.7 GHZ.

Aspects of this disclosure can be implemented in various electronic devices. Examples of the electronic devices can include, but are not limited to, consumer electronic products, parts of the consumer electronic products such as packaged radio frequency modules, uplink wireless communication devices, wireless communication infrastructure, electronic test equipment, etc. Examples of the electronic devices can include, but are not limited to, a mobile phone such as a smart phone, a wearable computing device such as a smart watch or an car piece, a telephone, a television, a computer monitor, a computer, a modem, a hand-held computer, a laptop computer, a tablet computer, a microwave, a refrigerator, a vehicular electronics system such as an automotive electronics system, a stereo system, a digital music player, a radio, a camera such as a digital camera, a portable memory chip, a washer, a dryer, a washer/dryer, a copier, a facsimile machine, a scanner, a multi-functional peripheral device, a wrist watch, a clock, etc. Further, the electronic devices can include unfinished products.

Unless the context clearly requires otherwise, throughout the description and the claims, the words “comprise,” “comprising,” “include,” “including” and the like are to be construed in an inclusive sense, as opposed to an exclusive or exhaustive sense; that is to say, in the sense of “including, but not limited to.” The word “coupled,” as generally used herein, refers to two or more elements that may be either directly connected, or connected by way of one or more intermediate elements. Likewise, the word “connected,” as generally used herein, refers to two or more elements that may be either directly connected, or connected by way of one or more intermediate elements. Additionally, the words “herein,” “above,” “below,” and words of similar import, when used in this application, shall refer to this application as a whole and not to any particular portions of this application. Where the context permits, words in the above Detailed Description using the singular or plural number may also include the plural or singular number respectively. The word “or” in reference to a list of two or more items, that word covers all of the following interpretations of the word: any of the items in the list, all of the items in the list, and any combination of the items in the list.

Moreover, conditional language used herein, such as, among others, “can,” “could,” “might,” “may,” “e.g.,” “for example,” “such as” and the like, unless specifically stated otherwise, or otherwise understood within the context as used, is generally intended to convey that certain embodiments include, while other embodiments do not include, certain features, elements and/or states. Thus, such conditional language is not generally intended to imply that features, elements and/or states are in any way required for one or more embodiments or that one or more embodiments necessarily include logic for deciding, with or without author input or prompting, whether these features, elements and/or states are included or are to be performed in any particular embodiment.

While certain embodiments have been described, these embodiments have been presented by way of example only, and are not intended to limit the scope of the disclosure. Indeed, the novel apparatus, methods, and systems described herein may be embodied in a variety of other forms; furthermore, various omissions, substitutions and changes in the form of the methods and systems described herein may be made without departing from the spirit of the disclosure. For example, while blocks are presented in a given arrangement, alternative embodiments may perform similar functionalities with different components and/or circuit topologies, and some blocks may be deleted, moved, added, subdivided, combined, and/or modified. Each of these blocks may be implemented in a variety of different ways. Any suitable combination of the elements and acts of the various embodiments described above can be combined to provide further embodiments. The accompanying claims and their equivalents are intended to cover such forms or modifications as would fall within the scope and spirit of the disclosure.

What is claimed is:

1. A surface acoustic wave device comprising:
a support substrate;
a first functional layer having a positive temperature coefficient of frequency disposed above an upper surface of the support substrate;
a second functional layer having a negative temperature coefficient of frequency disposed on an upper surface of the first functional layer;
a layer of piezoelectric material disposed on an upper surface of the second functional layer; and
interdigital transducer (IDT) electrodes including interdigitated electrode fingers disposed on a surface of the piezoelectric material layer, the IDT electrodes including a metal with a density greater than aluminum.

2. The surface acoustic wave device of claim 1 further comprising a trap-rich layer disposed between the support substrate and the first functional layer.

3. The surface acoustic wave device of claim 2 wherein the trap-rich layer is formed of polysilicon.

4. The surface acoustic wave device of claim 1 wherein the first functional layer is formed of silicon dioxide.

5. The surface acoustic wave device of claim 1 wherein the second functional layer is formed of a material exhibiting a greater acoustic velocity than the acoustic velocity of the material of the first functional layer.

6. The surface acoustic wave device of claim 5 wherein the second functional layer is formed of one of silicon nitride, silicon oxynitride, diamond, aluminum nitride, aluminum oxide, boron nitride, silicon carbide, cordierite, silicon oxycarbide, forsterite, magnesium aluminate spinel, magnesium titanate, yttrium oxide, samarium oxide, cerium oxide, hafnium oxide, tantalum oxide, zirconium titanate, barium nonatitante, niobium oxide, zirconium oxide, barium samarium titanate, titanium dioxide, or calcium titanate.

7. The surface acoustic wave device of claim 1 wherein the second functional layer is thinner than the first functional layer.

8. The surface acoustic wave device of claim 1 wherein the second functional layer is thinner than the layer of piezoelectric material.

9. The surface acoustic wave device of claim 1 wherein the first functional layer is thinner than the layer of piezoelectric material.

10. The surface acoustic wave device of claim 1 wherein the IDT electrodes include a first metal layer disposed on a second metal layer, the first metal layer being less dense and more conductive than the second metal layer.

11. The surface acoustic wave device of claim 10 wherein the first metal layer includes aluminum and the second metal layer includes one of molybdenum, tungsten, or platinum.

12. The surface acoustic wave device of claim 10 wherein the first metal layer has a thickness of between 0.025λ and 0.075λ, λ being a wavelength of a main acoustic wave generated by the surface acoustic wave device.

13. The surface acoustic wave device of claim 10 wherein the second metal layer has a thickness of between 0.0065λ and 0.08λ, λ being a wavelength of a main acoustic wave generated by the surface acoustic wave device.

14. The surface acoustic wave device of claim 1 wherein the surface acoustic wave device exhibits a temperature coefficient of frequency at its resonant frequency that has an absolute value of 10 ppm/° C. or less.

15. The surface acoustic wave device of claim 1 wherein the surface acoustic wave device exhibits a temperature coefficient of frequency at its anti-resonant frequency of less than −10 ppm/° C.

16. The surface acoustic wave device of claim 1 wherein the surface acoustic wave device exhibits an electromechanical coupling coefficient at its resonant frequency of at least 10%.

17. The surface acoustic wave device of claim 1 wherein the layer of piezoelectric material is formed of lithium tantalate.

18. A radio frequency filter comprising the surface acoustic wave device of any of claim 1.

19. An electronics module comprising the radio frequency filter of claim 18.

20. An electronic device including the electronics module of claim 19.
